(19) United States
(12) Patent Application Publication
(10) Pub. No.: US 2009/0026421 A1
(43) Pub. Date: Jan. 29, 2009

(54) OPTIMIZED LASER PYROLYSIS REACTOR AND METHODS THEREFOR

(76) Inventors: Xuegeng Li, Sunnyvale, CA (US); David Jurbergs, Austin, TX (US)

Correspondence Address: Foley & Lardner LLP, 150 East Gilman Street, Madison, WI, 53701-1497, US

(21) Appl. No.: 12/054,133

(22) Filed: Mar. 24, 2008

Related U.S. Application Data
(63) Continuation-in-part of application No. 11/967,568, filed on Dec. 31, 2007.
(60) Provisional application No. 60/920,471, filed on Mar. 27, 2007.
(60) Provisional application No. 60/881,869, filed on Jan. 22, 2007.

(51) Int. Cl. H01B 1/04; C23C 16/02; H01L 21/205

(52) U.S. Cl. 252/500; 118/716; 438/507; 257/E21.102

(57) ABSTRACT

An apparatus for making a set of Group IV nanoparticles is disclosed. The apparatus includes a top plate, the top plate further including an outlet port; a bottom plate; and a casing extending between the top plate and the bottom plate. The apparatus also includes a particle collector assembly configured to be in fluid communication with the outlet port; and a primary precursor tubing assembly passing through the bottom plate into the casing, the primary precursor tubing assembly including a primary precursor tubing assembly nozzle. The apparatus further includes a set of secondary precursor tubing assemblies passing through the bottom plate into the casing, wherein each secondary precursor tubing assembly of the set of secondary precursor tubing assemblies further includes a set of secondary precursor tubing assembly nozzles positioned orthogonally to the primary precursor tubing assembly nozzle, the set of secondary precursor tubing assembly nozzles further configured to be adjusted to a first height above primary precursor tubing assembly nozzle. The apparatus also includes a laser configured to generate a laser beam, the laser beam being substantially perpendicular to the primary precursor tubing assembly nozzle in the reaction zone, wherein the laser may be adjusted to a second height above primary precursor tubing assembly nozzle.

### CROSS-REFERENCE TO RELATED APPLICATIONS

This application claims the benefit of U.S. Patent Application Ser. No. 60/920,471 filed Mar. 27, 2007, entitled Laser Pyrolysis Reactor Apparatus for the Preparation of Group IV Semiconductor Nanoparticle Materials, and is a continuation-in-part of U.S. patent application Ser. No. 11/967,568 filed Dec. 31, 2007, entitled In Situ Modification of Group IV Nanoparticles Using Gas Phase Nanoparticle Reactors. The disclosures of both applications are incorporated herein by reference in their entirety.

### FIELD OF DISCLOSURE

This disclosure relates in general to Group IV nanoparticle production and in particular to an optimized laser pyrolysis reactor and methods therefore.

### BACKGROUND

The ability to deposit semiconductor materials using non-traditional semiconductor technologies such as printing may offer a way to simplify and hence reduce the cost of many modern electrical devices (e.g., computers, cellular phones, photovoltaic cells, etc.).

Like pigment in paint, these semiconductor materials are generally formed as microscopic particles, such as nanoparticles, and temporarily suspended in a colloidal dispersion that may be later deposited on a substrate. Laser pyrolysis, one particular method for the preparation of Group IV nanoparticles, offers a high volume, high throughput particle synthesis process.

For example, in U.S. Patent Application No. 20040229447, Swihart, et al (hereafter '447) a process is disclosed for the preparation of photoluminescent silicon nanoparticles using laser pyrolysis to produce the nanoparticles, and subsequently etching the particles to produce photoluminescent nanoparticle materials. In '447, an overview of attempts to produce silicon nanoparticle materials is given, in which the state of the art with respect to the stability of the nanoparticle surface is recognized in the art.

The methods described in '447 require a post-synthesis processing of the silicon nanoparticle materials. Such post-synthesis processing may subject the nanoparticles to conditions that have deleterious effects on the quality of such materials for a variety of optoelectric applications. Additionally, such post-processing steps may be impractical for producing large quantities of quality material at reasonable costs.

Therefore, there is a need in the art for laser pyrolysis apparatuses and methods that address the need for producing a variety of high quality Group IV nanoparticle materials in situ, obviating the need for costly post-processing steps.

### SUMMARY OF THE INVENTION

The invention relates, in one embodiment, to an apparatus for making a set of Group IV nanoparticles. The apparatus includes a top plate, the top plate further including an outlet port; a bottom plate; and a casing extending between the top plate and the bottom plate. The apparatus also includes a particle collector assembly configured to be in fluid communication with the outlet port; and a primary precursor tubing assembly passing through the bottom plate into the casing, primary precursor tubing assembly including a primary precursor tubing assembly nozzle. The apparatus further includes a set of secondary precursor tubing assemblies passing through the bottom plate into the casing, wherein each secondary precursor tubing assembly of the set of secondary precursor tubing assemblies further includes a set of secondary precursor tubing assembly nozzles positioned orthogonally to the primary precursor tubing assembly nozzle, the set of secondary precursor tubing assembly nozzles further configured to be adjusted to a first height above primary precursor tubing assembly nozzle. The apparatus also includes a laser configured to generate a laser beam, the laser beam being substantially perpendicular to the primary precursor tubing assembly nozzle in the reaction zone, wherein the laser may be adjusted to a second height above primary precursor tubing assembly nozzle.

The invention relates, in another embodiment, to a method for creating an organically capped Group IV semiconductor nanoparticle. The method includes flowing a Group IV semiconductor precursor gas into a chamber. The method also includes generating a set of Group IV semiconductor precursor radical species from the Group IV semiconductor precursor gas with a laser pyrolysis apparatus, wherein the set of the Group IV semiconductor precursor radical species nucleate to form the Group IV semiconductor nanoparticle; and flowing an organic capping agent precursor gas into the chamber. The method further includes generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

### BRIEF DESCRIPTION OF THE DRAWINGS

FIG. 1 shows a simplified schematic of an embodiment of a laser pyrolysis reactor system for the synthesis of embodiments of Group IV nanoparticles, in accordance with the invention;

FIG. 2 shows a simplified schematic of another embodiment of a laser pyrolysis reactor system for the synthesis of embodiments of Group IV nanoparticles;

FIG. 3 shows a simplified cross-section of an embodiment of a laser pyrolysis reactor subassembly for the synthesis of embodiments of Group IV nanoparticles;

FIG. 4 shows a simplified demonstration of factors impacting the synthesis of embodiments of Group IV nanoparticles using an embodiment of a laser pyrolysis reactor, in accordance with the invention; and

FIG. 5 shows the Fourier Transform Infrared (FTIR) spectra of silicon/silicon carbide core/shell nanoparticles prepared under different conditions, in accordance with the invention.

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In an advantageous manner, an optimized laser pyrolysis reactor may be configured for the large-scale production of Group IV nanoparticle core/shell nanoparticle materials. Such core/shell nanoparticles may have cores of silicon, germanium, and alpha-tin Group IV material; or alloys thereof. The shell may be of a variety of Group IV materials and combination thereof, or other materials, such as, for example, but not limited by, a variety of oxides, nitrides, carbides, and sulfides. In other embodiments, a stable organic passivation layer may be formed; either on a Group IV nanoparticle material, or on a core/shell nanoparticle. In still other embodiments, doped Group IV nanoparticle materials are produced using embodiments of laser pyrolysis reactor apparatuses described herein. Such doped materials can be used in embodiments of core/shell Group IV nanoparticle materials.

It is contemplated that Group IV semiconductor nanoparticles may be used in a variety of applications. Due to the luminescent properties of small nanoparticles, silicon and germanium nanoparticles have been contemplated for use in light-emitting applications, including use as phosphors for solid-state lighting, luminescent taggants for biological applications, security markers and related anti-counterfeiting measures. Other potential applications of Group IV semiconductor nanoparticles include a variety of optoelectronic devices, such as light-emitting diodes, photodiodes, photovoltaic cells, and sensors that utilize their unique optical and semiconductor properties. Because of the ability to produce colloidal forms of semiconductor nanoparticles, these materials offer the potential of low-cost processing, such as printing, that is not possible with conventional semiconductor materials.

Group IV nanoparticles have an intermediate size between individual atoms and macroscopic bulk solids. In some embodiments, Group IV nanoparticles have a size on the order of the Bohr exciton radius (e.g. 4.9 nm for silicon), or the de Broglie wavelength, which allows individual Group IV nanoparticles to trap individual or discrete numbers of charge carriers, either electrons or holes, or excitons, within the particle. The Group IV nanoparticles may exhibit a number of unique electronic, magnetic, catalytic, physical, optoelectronic and optical properties due to quantum confinement and surface energy effects. For example, Group IV nanoparticles exhibit luminescence effects that are significantly greater than, as well as melting temperatures of nanoparticles substantially lower than the complementary bulk Group IV materials.

These unique effects vary with properties such as size and elemental composition of the nanoparticles. For instance, as will be discussed in more detail subsequently, the melting of germanium nanoparticles is significantly lower than the melting of silicon nanoparticles of comparable size. With respect to quantum confinement effects, for silicon nanoparticles, the range of nanoparticle dimensions for quantum confined behavior is between about 1 nm to about 15 nm, while for germanium nanoparticles, the range of nanoparticle dimensions for quantum confined behavior is between about 1 nm to about 35 nm, and for alpha-tin nanoparticles, the range of nanoparticle dimensions for quantum confined behavior is between about 1 nm to about 40 nm. In another example, some embodiments of Group IV nanoparticles exhibit photoluminescence effects that are significantly greater than the photoluminescence effects of macroscopic materials having the same composition. Such these photoluminescence effects vary as a function of the size of the nanoparticle, so that light emitted, and hence color emitted in the visible portion of the electromagnetic spectrum is a quantum confinement effect that varies with nanoparticle size.

As used herein, the term “Group IV nanoparticle” generally refers to hydrogen terminated Group IV nanoparticles having an average diameter between about 1.0 nm to 100.0 nm, and composed of silicon, germanium, and alpha-tin, or combinations thereof. As will be discussed subsequently, some embodiments of Group IV nanoparticles are doped. With respect to shape, embodiments of Group IV nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, polycrystalline, or amorphous in nature. As such, a variety of types of Group IV nanoparticle materials may be created by varying the attributes of composition, size, shape, and crystallinity of Group IV nanoparticles. Exemplary types of Group IV nanoparticle materials are yielded by variations including, but not limited by: single or mixed elemental composition (including alloys, core/shell structures, doped nanoparticles, and combinations thereof); single or mixed shapes and sizes, and combinations thereof; and single form of crystallinity or a range or mixture of crystallinity, and combinations thereof.

It is contemplated that a variety of Group IV nanoparticle materials having suitable quality for a variety of uses can be produced using embodiments of laser pyrolysis apparatuses described herein. Particle quality includes, but is not limited by, particle morphology, average size and size distribution. For embodiments of disclosed Group IV nanoparticles, suitable nanoparticle materials useful as starting materials have distinct particle morphology, with low incidence of particle clumping, agglomeration, or fusion. As mentioned previously, the properties that are imparted for Group IV nanoparticles are related closely to the particle size. In that regard, for many applications, a monodisperse population of particles of specific diameter is also indicated.

For the Group IV nanoparticle materials, the surface area to volume ratio, which is inversely proportional to radius, is in the range of a thousand times greater than for colloids in the 1.0 micron range. These high surface areas, as well as other factors, such as, for example, the strain of the Group IV atoms at curved surfaces, are conjectured to account for what the inventors have observed, which has not been generally reported in the literature, as the extraordinary reactivity of the Group IV nanoparticles. As a result of this observation, embodiments of the disclosed Group IV nanoparticle materials are maintained in an inert environment until they are stably processed, so that for the target application the material so produced has the highest quality for the intended use.

For example, stabilized luminescence is observed for Group IV nanoparticles that have been organically capped. Phenomena such as high quantum yield and intensity of photoluminescence emitted from such embodiments of organically capped Group IV nanoparticles is observed. With respect to semiconductor properties, the inventors' have observed that by keeping embodiments of the native Group IV nanoparticles in an inert environment from the moment the particles are formed through the formation of Group IV semiconductor thin films, that such thin films so produced have properties characteristic of native bulk semiconductor materials. In that regard, such thin films are formed from materials for which the spectral absorbance, photovoltaic and photoconductive properties are well characterized. This is in contrast, for example, to the use nanoparticles mixed with organic modifiers. In some such modifications, the Group IV nanoparticle materials are significantly oxidized. The use of these types of nanoparticle materials produces hybrid thin films, which hybrid thin films do not have as yet the same desirable properties as traditional Group IV materials.

The first step for producing embodiments of Group IV nanoparticles is to produce quality nanoparticles in an inert environment using embodiments of laser pyrolysis reactor apparatuses described herein. For the purposes of this disclosure, an inert environment is an environment in which there are no fluids (i.e. gases, solvents, and solutions) that react in such a way that they would negatively affect properties such as the semiconductor, photoelectrical, and luminescent properties of the Group IV nanoparticles. In that regard, an inert gas is any gas that does not react with embodiments of Group IV nanoparticles in such a way that it negatively affects the properties of the Group IV nanoparticles for their intended use. Likewise, an inert solvent is any solvent that does not react with embodiments of Group IV nanoparticles in such a way that it negatively affects the properties of the Group IV nanoparticles for their intended use. Finally, an inert solution is a mixture of two or more substances that does not react with Group IV nanoparticles in such a way that it that it negatively affects the properties of the Group IV nanoparticles for their intended use.

Examples of inert gases that may be used to provide an inert environment include nitrogen and the rare gases, such as argon. Though not limited by defining inert as only oxygen-free, since other fluids may react in such a way that they negatively affect the semiconductor, photoelectrical, and luminescent properties of the Group IV nanoparticles, it has been observed that a substantially oxygen-free environment is indicated for producing suitable Group IV nanoparticles. As used herein, the terms “substantially oxygen free” in reference to environments, solvents, or solutions refer to environments, solvents, or solutions wherein the oxygen content has been reduced in an effort to eliminate or minimize the oxidation of the Group IV nanoparticles in contact with those environments, solvents, or solutions. As such, the Group IV nanoparticles starting materials are fabricated in inert, substantially oxygen-free conditions until they are stably processed.

For some embodiments of Group IV nanoparticles used for example in photoluminescent applications, substantially oxygen-free conditions will contain no more than about 100 ppm oxygen (O₂). This includes embodiments where the substantially oxygen-free conditions contain no more than about 1 ppm oxygen and further includes embodiments where the substantially oxygen-free conditions contain no more than about 100 ppb oxygen. For photovoltaic and photoconductive applications of Group IV nanoparticles, “inert” refers to environments, solvents, or solutions wherein the oxygen content has been substantially reduced to produce, for example, Group IV semiconductor thin films having no more than 10¹⁷ to 10¹⁹ oxygen per cubic centimeter of Group IV semiconductor thin film. In that regard, if the Group IV nanoparticle materials are reactive after preparation, such as for example a silicon/germanium core/shell nanoparticle material, such material should be maintained under vacuum or an inert, substantially oxygen-free atmosphere until it has been stably processed. In another example, some embodiments of inks formulated using such reactive Group IV nanoparticle materials are made in anhydrous, deoxygenated solvents or solutions held under vacuum or inert gas to minimize the dissolved oxygen content in the liquid until the nanoparticle material is stably processed.

In one aspect of Group IV nanoparticle materials using gas phase reactors, embodiments of core/shell particles can be prepared. For example, in the fabrication of photovoltaic thin films, it is desirable to adjust the band gap of embodiments of Group IV photoconductive thin films. For Group IV nanoparticle materials used to fabricate such thin films, the band gap of silicon is about 1.1 eV, while the band gap of germanium is about 0.7 eV, and for alpha-tin is about 0.05 eV. This may be done through formulations of single or mixed elemental composition of silicon; germanium and tin nanoparticles in core/shell structures, as well as alloys, doped nanoparticles, and combinations thereof. Embodiments of the Group IV core/shell nanoparticle materials so formed can be specifically designed to provide the targeted thin film band property. As previously discussed, Group IV nanoparticle core materials can be prepared having a variety of shell materials, for example, but not limited by, carbide, nitride, sulfide, and oxide shell compositions.

Various embodiments of Group IV semiconductor nanoparticle inks can be formulated by the selective blending of different types of Group IV semiconductor nanoparticles. Ink formulations having various properties may be formulated for deposition on a variety of substrates to fabricate a variety of optoelectric devices as previously described.

For example, varying the packing density of Group IV semiconductor nanoparticles in a deposited thin layer is desirable for forming a variety of embodiments of Group IV photoconductive thin films. In that regard, Group IV semiconductor nanoparticle inks can be prepared in which various sizes of monodispersed Group IV semiconductor nanoparticles are specifically blended to a controlled level of polydispersity for a targeted nanoparticle packing. Further, Group IV semiconductor nanoparticle inks can be prepared in which various sizes, as well as shapes are blended in a controlled fashion to control the packing density.

Additionally, particle size and composition may impact fabrication processes, so that various embodiments of inks may be formulated that are specifically tailored to thin film fabrication. This is due to that fact that there is a direct correlation between nanoparticle size and melting temperature. For example, for silicon nanoparticles between a size range of about 1 nm to about 15 nm, the melting temperature is in the range of between about 400° C. to about 1100° C. versus the melting of bulk silicon, which is 1420° C. For germanium, nanoparticles of in a comparable size range of about 1 nm to about 15 nm melt at a lower temperature of between about 100° C. to about 800° C., which is also significantly lower than the melting of bulk germanium at about 935° C. Therefore, the melting temperatures of the Group IV nanoparticle materials as a function of size and composition may be exploited in embodiments of ink formulations for targeting the fabrication temperature of a Group IV semiconductor thin film.

Another example of what may be achieved through the selective formulation of Group IV semiconductor nanoparticle inks by blending doped and undoped Group IV semiconductor nanoparticles. For example, various embodiments of Group IV semiconductor nanoparticle inks can be prepared in which the dopant level for a specific thin layer of a targeted device design is formulated by blending doped and undoped Group IV semiconductor nanoparticles to achieve the requirements for that layer. In still another example are embodiments of Group IV semiconductor nanoparticle inks that may compensate for defects in embodiments of Group IV photoconductive thin films. For example, it is known that in an intrinsic silicon thin film, oxygen may act to create undesirable energy states. To compensate for this, low levels of p-type dopants, such as boron difluoride, trimethyl borane, or diborane, may be used to compensate for the presence of low levels of oxygen. By using Group IV semiconductor nanoparticles to formulate embodiments of inks, such low levels of p-type dopants may be readily introduced in embodiments of blends of the appropriate amount of p-doped Group IV semiconductor nanoparticles with various types of undoped Group IV semiconductor nanoparticles.

Other embodiments of Group IV semiconductor nanoparticle inks can be formulated that adjust the band gap of embodiments of Group IV photoconductive thin films. For example, the band gap of silicon is about 1.1 eV, while the band gap of germanium is about 0.7 eV, and for alpha-tin is about 0.05 eV. Therefore, formulations of Group IV semiconductor nanoparticle inks may be selectively formulated so that embodiments of Group IV photoconductive thin films may have photon adsorption across a wider range of the electromagnetic spectrum. This may be done through formulations of single or mixed elemental composition of silicon; germanium and tin nanoparticles, including alloys, core/shell structures, doped nanoparticles, and combinations thereof. Embodiments of such formulations of may also leverage the use of single or mixed shapes and sizes, and combinations thereof, as well as a single form of crystallinity or a range or mixture of crystallinity, and combinations thereof.

Still other embodiments of inks can be formulated from alloys and core/shell Group IV semiconductor nanoparticles. For example, it is contemplated that silicon carbide semiconductor nanoparticles are useful for in the formation of a variety of semiconductor thin films and semiconductor devices. In other embodiments, alloys of silicon and germanium are contemplated. Such alloys may be made as discrete alloy nanoparticles, or may be made as core/shell nanoparticles.

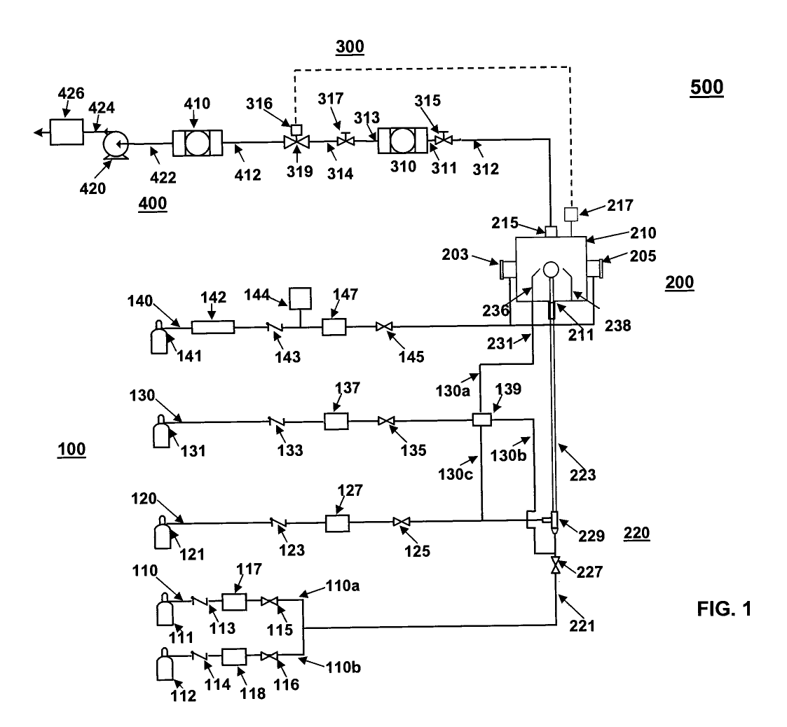

FIG. 1 depicts a generalized schematic of an embodiment of a laser pyrolysis reactor apparatus 500 for the fabrication of doped Group IV nanoparticles. Laser pyrolysis reactor apparatus 500 is comprised of a gas line subassembly 100, a laser pyrolysis reactor subassembly 200, a nanoparticle collection subassembly 300, and an exhaust subassembly 400.

For laser pyrolysis reactor gas line subassembly 100, a plurality of gas lines as shown in FIG. 1 may be used. A primary precursor gas line 110 may include two lines 110a and 110b. Line 110a has a primary precursor gas source 111, as well as first and second valves 113 and 115 for flow control, and further includes, a first primary precursor gas line mass flow controller 117. Optional line 110b is an inert diluent gas line, and includes diluent gas source 112, as well as first and second valves 114 and 116 for flow control, and further includes, a primary precursor gas line mass flow controller 118. All elements comprising the primary precursor gas line 110 are in fluid communication with one another through primary precursor gas line 110, and primary precursor gas line 110 is also in fluid communication with laser pyrolysis reactor subassembly 200.

A sheath flow gas line 120 is used for delivering an inert sheath gas to the laser pyrolysis reactor subassembly 200, as will be discussed more subsequently. Sheath flow gas line 120 includes a sheath flow gas source 121, and has first and second valves 123 and 125 for flow control, and further, a sheath flow gas mass flow controller 127. All elements comprising the sheath flow gas line 120 are in fluid communication with one another through sheath flow gas line 120, and sheath flow gas line 120 is also in fluid communication with laser pyrolysis reactor subassembly 200. A secondary precursor gas line 130 has a secondary precursor gas source 131, and first and second valves 133 and 135 for flow control, and further includes a secondary precursor gas line mass flow controller 137. Optionally, secondary precursor gas line 130 may be configured in a similar fashion to primary precursor gas line 110, and also include a diluent gas and diluent gas line.

All elements comprising the secondary precursor gas line 130 are in fluid communication with one another through secondary precursor gas line 130, and secondary precursor gas line 130 is also in fluid communication with laser pyrolysis reactor subassembly 200. Secondary precursor gas line 130 could be used, for example, but not limited by, as a dopant gas line, or as an organic capping agent gas line. As shown, secondary precursor gas line 130 may be shunted via three-way valve 139 through lines 130a, 130b, or 130c to different lines leading to laser pyrolysis reactor subassembly 200, as will be discussed in more detail subsequently. A chamber purge gas line 140 is used for delivering an inert gas to the chamber to purge optical chamber ports, such as optical chamber ports 203 and 205. Chamber purge gas line 140 includes an inert chamber purge gas source 141, and has first and second valves 143 and 145 for flow control, and further includes chamber purge gas mass flow controller 147. Optionally, a chamber purge gas line trap 144 for scrubbing impurities, such as oxygen and water from the chamber purge gas in order to render it inert, and a chamber purge gas line analyzer 146 for monitoring impurities, such as oxygen and water levels to ensure that they are effectively removed from the carrier gas lines may also be included.

Though shown for chamber purge gas line 140 for example, such gas line traps and gas line analyzers may be used on any gas line shown for laser pyrolysis gas line subassembly 100. All elements comprising the chamber purge gas line 140 are in fluid communication with one another through chamber purge gas line 140, and chamber purge gas line 140 is also in fluid communication with laser pyrolysis reactor subassembly 200.

Laser pyrolysis reactor subassembly 200, an embodiment of which is depicted in the cross section of FIG. 1, includes a laser pyrolysis reactor chamber 210, having an inlet port 211, an outlet port 215, a first optical chamber port 203, a second optical chamber port 205, and a laser pyrolysis reactor chamber pressure sensor 217. Laser pyrolysis reactor inlet line subassembly 220 is a concentric ensemble of a first inner line 221, and a second outer line 223 led into the chamber 210 through the laser pyrolysis chamber inlet port 211. First inner line 221 has a first inner line valve 227, and the concentric ensemble is created using fitting 229, which may be for example, a combination of a bore-through union and a bore through tee. A first set of first and second secondary precursor gas nozzles 236 and 238 may be in fluid communication via secondary precursor nozzle inlet line 231 with the secondary precursor gas source 131 through secondary precursor gas line 130a using three-way valve 139. The secondary precursor gas source 131 may also be in fluid communication with the laser pyrolysis reactor subassembly 200 using three-way valve to shunt secondary precursor gas to first inner line 221 of laser pyrolysis reactor inlet line subassembly 220 via secondary precursor gas line 130b. Finally, the secondary precursor gas source 131 may also be in fluid communication with the laser pyrolysis reactor subassembly 200 using three-way valve to shunt secondary precursor gas to second outer line 223 of laser pyrolysis reactor inlet line subassembly 220 via secondary precursor gas line 130c. Additionally, laser pyrolysis reactor subassembly 200 is in fluid communication with the nanoparticle collection subassembly 300 via the nanoparticle collector inlet line 312 emanating from the laser pyrolysis reactor subassembly 200 through the laser pyrolysis reactor outlet port 215.

The nanoparticle collector subassembly 300 has a nanoparticle collector 310, having a nanoparticle collector inlet end 311 and a nanoparticle collector outlet end 313. A nanoparticle collector inlet line 312, with nanoparticle collector inlet valve 315, is joined to the nanoparticle collector 300 via the inlet end 311. A nanoparticle collector outlet line 314, with nanoparticle collector outlet valves 317 and 319, is joined to the nanoparticle collector 300 via the outlet end 313. A pressure control system for particle collector 310 is composed of a laser pyrolysis reactor chamber pressure sensor 217, a nanoparticle collection valve controller 316, and a throttle valve, for example, such as a butterfly valve 319. During typical operation, inlet valve 315 and outlet valve 317 are open, but butterfly valve 319 is partially open. As particles are collected in particle collector 310, pressure builds up, and is detected by laser pyrolysis reactor chamber pressure sensor 217, which through nanoparticle collection valve controller 316 opens butterfly valve 319 to keep the pressure constant. Nanoparticle collector subassembly 300 is in fluid communication with the exhaust subassembly 400 via the dust collector inlet line 412, which is joined to the dust collector 410. The effluent gas flows from the dust collector 410 out through the vacuum pump inlet line 422 into the vacuum pump 420, and exits to atmosphere through the vacuum pump outlet line 424, through the mist trap 426.

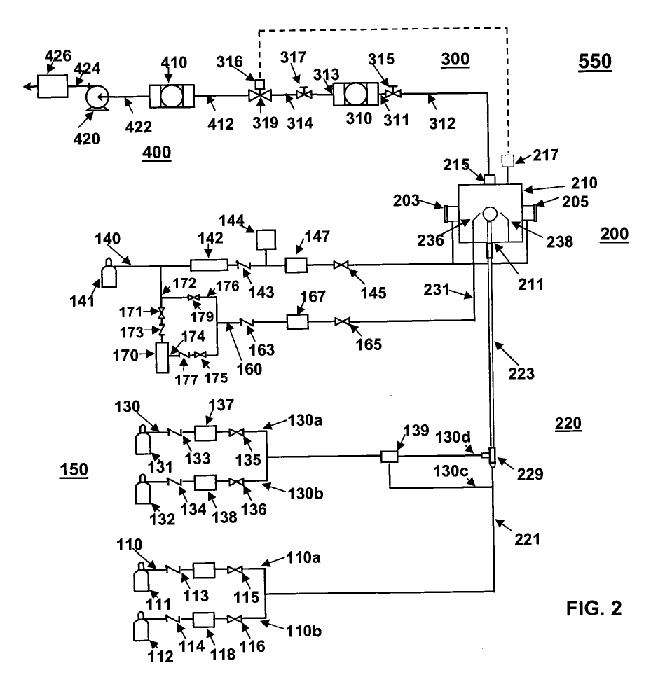

In FIG. 2, an alternative embodiment of a laser pyrolysis apparatus 550 having laser pyrolysis reactor gas line subassembly 150 is shown. In laser pyrolysis apparatus 550, another embodiment of a secondary precursor gas line for use with liquid secondary precursor materials is displayed. Secondary liquid precursor vapor line 160 utilizes an inert carrier gas from chamber purge gas line 140. In order to operate the secondary liquid precursor vapor line 160, the inert carrier gas from the chamber purge gas line 140 flows into secondary precursor liquid chamber 170 via secondary precursor liquid inlet line 172, having a first valve 171 and a second valve 173. Secondary precursor liquid chamber 170 may be thermostatted in order to control the partial pressure of secondary precursor gas vapor in the head space over the secondary precursor gas liquid. The head space above the secondary precursor liquid flows from the secondary precursor liquid chamber 170 to secondary liquid precursor vapor line 160 via secondary precursor liquid outlet line 174, having a first valve 175 and a second valve 177. Secondary precursor liquid bypass line 176 with valve 179 is used to purge secondary liquid precursor vapor line 160 using inert gas source 141.

When the secondary precursor liquid bypass line 176 is closed, and the secondary precursor liquid inlet line 172 and secondary precursor liquid outlet line 174 are open, inert carrier gas may enter the secondary liquid precursor chamber 170; possibly even being bubbled through a secondary precursor liquid, and then sweeps the head space above the secondary precursor liquid in the secondary precursor liquid chamber 170, carrying secondary precursor gas vapors into secondary liquid precursor vapor line 160 thereby. Control features on secondary liquid precursor vapor line 160 include valves 163, and 165, as well as mass flow controller 167. Secondary liquid precursor vapor line 160 is in fluid communication with a first set of first and second secondary precursor gas nozzles 236 and 238 via secondary precursor nozzle inlet line 231. Additionally, secondary precursor gas line 130 of laser pyrolysis reactor gas line subassembly 150 may include a diluent gas line, as previously described for primary precursor gas line 110 of FIG. 1. Secondary precursor line 130 of laser pyrolysis reactor gas line subassembly 150 has two-way valve 139, which can either shunt secondary precursor gas into first inner line 221 of laser pyrolysis reactor inlet line subassembly 220 via secondary precursor gas line 130c or to second outer line 223 of laser pyrolysis reactor inlet line subassembly 220 via secondary precursor gas line 130d.

Unless otherwise designated, all valves indicated for the generalized gas phase reactor apparatus, such as valves 113, 114, 123, 133, and 143 of laser pyrolysis reactor gas line subassembly 100 shown in FIG. 1 are check valves. Valves such as valves 115, 116, 125, 135 and 145 of laser pyrolysis reactor gas line subassembly 100 shown in FIG. 1 are positive shut-off valves, such as ball, diaphragm, bellows, toggle, and plug valves. Additionally, all gas line conduits and fittings used are stainless steel. For example, the but not restricted by, the gas lines of laser pyrolysis reactor gas line subassembly 100 shown in FIG. 1; such as gas lines 110, 120, 130, and 140 may be stainless steel having outer diameters of between about 0.125″ OD to about 0.250″ OD, with inner diameters of between about 0.069″ ID to about 0.152″ ID, respectively. The laser pyrolysis reactor inlet line subassembly 220 may be formed from stainless steel tubing, wherein the second outer line 223 of FIG. 1 is between about 0.375″ OD to about 0.500″ OD, with inner diameters of between about 0.305″ ID to about 0.430″ ID, respectively. Both the second outer line 221 of laser pyrolysis reactor inlet line subassembly 220 as well as secondary precursor gas nozzles 236 and 238 of FIG. 1 are prepared from stainless steel tubing between about 0.0625″ OD to about 0.125″ OD, with inner diameters of between about 0,020″ ID to about 0.085″ ID, respectively. All gas lines from laser pyrolysis outlet port 215 to the exhaust are QF40 stainless steel piping.

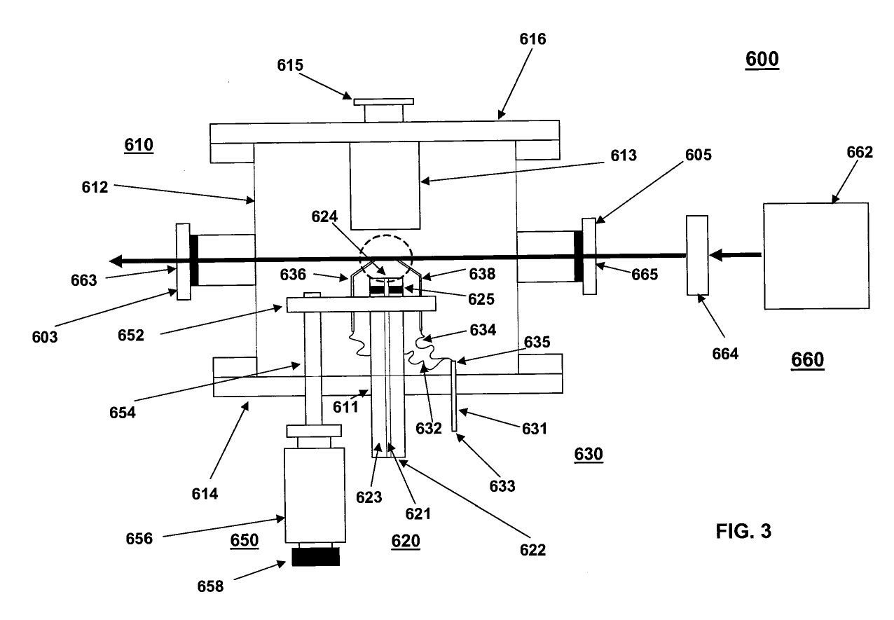

In FIG. 3, a schematic showing the cross-section of another embodiment of a laser pyrolysis reactor assembly 600, which has features in addition to those shown for laser pyrolysis reactor assembly 200 in FIG. 1 and FIG. 2. The laser pyrolysis reactor chamber 610 is composed of a casing 612, a bottom plate 614, and top plate 616.

The primary precursor conduit or tubing assembly 620 passes through the bottom plate 614 via bottom plate port 611. The primary precursor conduit or tubing assembly 620 is composed of a first inner conduit or tubing 621 and a second outer conduit or tubing 623. The concentric arrangement of inner conduit 621 and outer conduit 623 is maintained by spacer 625, which is made of a porous material, such as stainless steel, ceramic, or glass. The primary precursor conduit assembly 620 has an inlet end 622, which is in fluid communication with gas line subassembly 100 of FIG. 1 and an outlet end 624, which is in fluid communication with laser pyrolysis reactor outlet port 615. A first secondary precursor conduit assembly 630 is composed of secondary precursor nozzle inlet line 631, having an inlet end 633, and an outlet end 635. Inlet end 633 may be in fluid communication with a gas source line, such as secondary precursor gas line 130 of FIG. 1, or such as secondary liquid precursor gas line 160 of FIG. 2.

Outlet end 635 is in fluid communication with a first secondary precursor nozzle tubing 632, and second secondary precursor nozzle tubing 634. The first secondary precursor nozzle tubing 632 is in fluid communication with a first secondary precursor nozzle 636, while the second secondary precursor nozzle tubing 634 is in fluid communication with a second secondary precursor nozzle 638. A second secondary precursor conduit assembly 640, not shown, and identical with respect to the elements described for first secondary precursor conduit assembly 630 is mounted in an axis orthogonal to the axis in which secondary precursor conduit assembly 630 is mounted, yielding a total of four nozzles symmetrically distributed in the vicinity of particle formation. In this fashion, the secondary precursor gas flow of the secondary precursor gas is evenly distributed around the area in which the particles are formed, which is indicated in the cross-section by the hatched circle. Though two secondary precursor nozzle assembles are described herein, higher order assemblies and nozzle designs are possible, as would be apparent to one of ordinary skill in the art.

In order to adjust the secondary precursor gas nozzles with great precision and accuracy, secondary precursor gas nozzle height adjustment assembly 650 of FIG. 3 is used. Secondary precursor nozzle height adjustment assembly 650 of FIG. 3 is composed of stage 652, in which the secondary precursor gas nozzles, such as 636, 638 are mounted. Stage 652 is mounted on shaft 654, which is connected to handle 656. The height of stage 652, and therefore of secondary precursor gas nozzles, such as 636, 638 can be made using adjustment knob 658. As one of ordinary skill in the art is apprised, such stage assemblies are capable of controlling height adjustments to fractions of a millimeters, providing highly precise and accurate adjustment of the nozzle height relative to outlet end 624 of the primary precursor conduit assembly 620. Finally, top plate 616 has particle collector conduit 613, which accumulates and guides the nanoparticles produced towards the laser pyrolysis reactor outlet port 615. The laser pyrolysis reactor outlet port 615 with is in fluid communication with both a particle collector assembly, such as the particle collector subassembly 300 of FIG. 1 and an exhaust subassembly, such as the exhaust subassembly 400 of FIG. 1.

The optical assembly 660 of laser pyrolysis reactor assembly 600 of FIG. 3 is composed of a laser 662, optionally a focusing lens 664a first optical port 603, with first optical port window 663 and a second optical port 605, with second optical port window 665. Orthogonal to the line of sight through first and second optical ports 603, 605, and therefore not apparent in this cross section, are third and forth optical ports 607, 609, with third and forth optical port windows 667 and 669, respectively (not apparent in the plane of the cross-section of FIG. 3), which are used for operator viewing. The dark line emanating from laser source 662 through first optical port window 663 indicates the direction of the laser beam through the laser pyrolysis reactor assembly 600. The laser needs to have wavelength and power specification suitable for the decomposition of the primary precursor gases in order to form the Group IV nanoparticles.

A carbon dioxide (CO₂) laser, having a wavelength of 10.59 microns, and capable of delivering between about 30 W to about 300 W; operating either in the continuous wave or pulsed beam mode, and having an unfocused beam diameter of between about 4 mm to about 8 mm is an example of a laser suitable for use for the laser pyrolysis preparation of Group IV nanoparticles. The window material for the optical port windows 663, 665, 667, and 669 and other optical material, such as the focusing lens 664 should be durable both chemically and mechanically, and capable of transmission of the light from the laser light source. An example of a suitable window material for use with a CO₂ laser is zinc selenide.

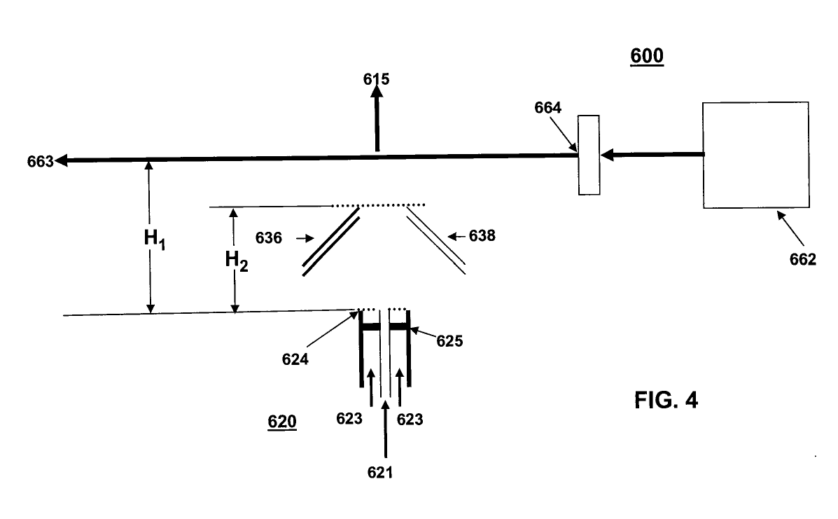

Referring to FIG. 4, the height adjustment of the secondary precursor gas nozzles is important for optimizing the conditions for modification of Group IV nanoparticles using a secondary precursor gas once the nanoparticles are formed using a primary precursor gas, as will be discussed in more detail subsequently. In FIG. 4, two heights are indicated. The first height, H₁ is the height between the secondary precursor nozzles, such as 636, 638, and the center of laser beam, which laser beam is indicated by the arrowed line directed from laser source 662 towards first optical port window 663. The height H₁ is affected by the adjustment of the laser beam position. The second height, H₂ is the height between the outlet end 624 of primary precursor conduit or tubing assembly 620, and the tips of the secondary precursor nozzles, such as 636, 638. The second height, H₂ is adjusted using secondary precursor nozzle height adjustment assembly 650 shown in FIG. 3.

### EXAMPLE 1

Two sets of silicon core/silicon nitride shell silicon nanoparticles were made in a laser pyrolysis apparatus in accordance with the invention. A first set was prepared with in which the height of the set of secondary precursor tubing assembly nozzles was 4 mm. A second set was prepared in which the height of the set of secondary precursor tubing assembly nozzles was 5.25 mm.

The conditions for producing the core/shell nanoparticles were a primary precursor gas flow of 40 sccm of silane gas, using no make-up flow of inert gas. The helium sheath gas flow through second outer laser pyrolysis reactor inlet line, such as second outer laser pyrolysis reactor inlet line 223 of FIG. 1 was 500 sccm. The flow rate of the secondary precursor gas through secondary precursor gas nozzles, such as the secondary precursor nozzles 236, 238 of FIG. 1 was 300 sccm of ammonia. The optical ports, such as the optical ports 203 and 205 of FIG. 1, were purged using helium run at 2500 sccm through a chamber purge gas line, such as chamber purge gas line 140 of FIG. 1. The chamber pressure under these conditions was 650 Torr. The laser power was 104 W, with a beam height (H₁ of FIG. 4) of 1.5 mm.

As could be seen in electron micrograph (TEM) images the particles generated with a secondary precursor tubing assembly nozzle height of about 4 mm did not dissolve in 1M KOH. In contrast, the particles generated with a secondary precursor tubing assembly nozzle height of about 5.25 mm did dissolve in 1M KOH. That is, the particles produced at 4 mm were generally more robust, due to a complete and impermeable silicon nitride shell that is inert to base treatment. This example demonstrates the significance of factors such as the height adjustment of the nozzles and the laser beam in producing high quality Group IV nanoparticle materials.

### EXAMPLE 2

Two sets of silicon core/silicon nitride shell silicon nanoparticles were made in a laser pyrolysis apparatus, in accordance with the invention. A first set was made in which the ratio of an ethylene secondary precursor gas to a silane primary precursor gas was 1:8.3. A second set was made in which the ratio of an ethylene secondary precursor gas to a silane primary precursor gas was 1:0.5.

The first set of particles was produced with a primary silane precursor gas flow of about 60 sccm, and a secondary ethylene precursor gas flow rate of about 250 sccm. The second set of particles was produced with a primary silane precursor gas flow of about 60 sccm, and a secondary ethylene precursor gas flow rate of about 30 sccm.

In this example, the three-way valve 139 on secondary precursor gas line 130 of FIG. 1 was positioned so that the primary and secondary precursor gases were mixed through first inner laser pyrolysis reactor inlet line, such as line 221 of FIG. 1, while helium was used for sheath flow, and therefore fed through second outer laser pyrolysis reactor inlet line, such as line 223 of FIG. 1.

A helium sheath gas was flowed through a second outer laser pyrolysis reactor inlet line, such as second outer laser pyrolysis reactor inlet line 223 of FIG. 1 was 1000 sccm. The optical ports, such as the optical ports 203 and 205 of FIG. 1, which are orthogonal to optical ports 603 and 605 of FIG. 3, were purged using helium run at 2000 sccm through a chamber purge gas line, such as chamber purge gas line 140 of FIG. 1. The chamber pressure was 500 Torr. The laser power was about 150 W, with a beam height (H₁ of FIG. 4) of 1.0 mm.

As could be seen in electron micrograph (TEM) images the first set of particles did not dissolve in 1M KOH. In contrast, the second set of particles did dissolve in 1M KOH. That is, the first set of particles were generally more robust, due to a complete and impermeable silicon carbide shell that is inert to base treatment. This example demonstrates the significance of factors such as the ratio of the primary and secondary precursor gases.

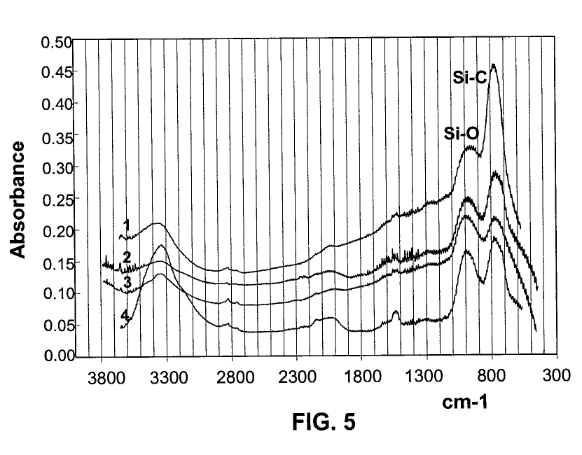

Referring now to FIG. 5, a series of Fourier Transform Infrared (FTIR) spectra are shown for batches of silicon/silicon carbide nanoparticles produced varying the height of H₂ of FIG. 4. As shown in FIG. 4, the height of H₂ is the height of the injection nozzles, such as nozzles 636 and 638 of FIG. 3, relative to the outlet end of the secondary precursor conduit or tubing ensemble, such as the outlet end 624 of secondary precursor conduit or tubing ensemble 620 of FIG. 3.

For the silicon/silicon carbide core/shell nanoparticle materials of Example 1, the nozzle height H₂ was 2.7 mm, and correlates to FTIR spectra 1. The peak at about 800 cm⁻¹ attributed to a silicon-carbon mode and the peak at about 1000 cm⁻¹ attributed to a silicon-oxygen mode, are the peaks of interest for evaluating the silicon/silicon carbide nanoparticle materials produced varying the nozzle height H₂.

For stably coated silicon nanoparticle material, the silicon-carbon peak is predominant, while the silicon-oxygen peak is a small shoulder. In the remaining spectra 2-4, the nozzle height H₂ was progressively increased to 4 mm, 5.25 mm, and 9 mm, respectively. As the silicon-carbon peak diminished relative to the silicon-oxygen peak, the particles went from being insoluble in 1M KOH (nanoparticle materials of spectra 1 and spectra 2) to soluble in 1M KOH (nanoparticle materials of spectra 3 and spectra 4). This serves to illustrate the impact of nozzle height H₂ in optimizing robust core/shell nanoparticle materials using a laser pyrolysis apparatus, such as an embodiment represented by the combination of a laser pyrolysis apparatus, such as laser pyrolysis apparatus 500 of FIG. 1, combined with the laser pyrolysis reactor subassembly, such as that of FIG. 3.

### EXAMPLE 3

A set of silicon core/zinc sulfide shell silicon nanoparticles were made in a laser pyrolysis apparatus, in accordance with the invention. One of the secondary precursor materials for the shell, the dimethyl zinc, is a liquid material.

A primary precursor silane gas was flowed at about 60 sccm, with make-up hydrogen flowed at about 170 sccm through first inner laser pyrolysis reactor inlet line, such as 221 of FIG. 2. Instead of a helium sheath gas flow through second outer laser pyrolysis reactor inlet line, such as 223 of FIG. 2, the gaseous secondary precursor, hydrogen sulfide, was shunted through the second outer line using a secondary precursor line such as such as secondary precursor line 130d of FIG. 2 at a flow rate of 200 sccm with a make-up flow of hydrogen of 300 sccm.

Helium gas was bubbled through a solution of dimethyl zinc solution as previously described for gas line subassembly 150 of FIG. 2. Recalling in such an example, when the secondary precursor liquid inlet line 172 and secondary precursor liquid outlet line 174 are open, an inert carrier gas, such as from gas source 141 of FIG. 2, may be bubbled through the secondary precursor solution. The carrier gas flow carries the secondary precursor vapors in the head space above the secondary precursor liquid in the secondary precursor liquid chamber 170, into secondary liquid precursor vapor line 160. The flow rate of the helium carrier gas and dimethyl zinc secondary precursor gas vapor was 400 sccm, and was directed through precursor gas nozzles, such as the secondary precursor nozzles 236, 238 of FIG. 1.

The optical ports, such optical ports 203 and 205 of FIG. 1, were purged using helium run at 1500 sccm through a chamber purge gas line, such as chamber purge gas line 140 of FIG. 2. The chamber pressure was 200 Torr. The laser power was 54 W, with a beam height (H₁ of FIG. 4) of 5.25 mm. Under these conditions, the embodiment of the silicon/zinc sulfide core/shell nanoparticle of FIG. 8 was insoluble in 1M KOH.

In addition to embodiments of core/shell nanoparticles, embodiments of organically capped Group IV nanoparticle materials are contemplated. One example of a reaction that is used for creating an organic passivation layer on Group IV nanoparticle materials is an insertion reaction between the hydrogen-terminated Group IV atoms at the nanoparticles surface and alkenes or alkynes. For the Group IV nanoparticles of interest, which are silicon, germanium, and tin; as well as core/shell nanoparticle and alloy nanoparticle materials thereof, the reaction is referred to as hydrosilylation, hydrogermylation, and hydrostannylation, respectively. In solution, various suitable protocols for this class of insertion reaction are known. Such protocols include the use of a free-radical initiator, thermally induced insertion, photochemical insertion using ultraviolet or visible light, and metal complex mediated insertion. Descriptions of protocols for the above described insertion reaction in solution, and other known reactions in solution for forming Group IV element-carbon bonds may be found in J. M. Buriak, Chem. Rev., vol. 102, pp. 1271-1308 (2002), the entire disclosure of which is incorporated herein by reference.

The inventors have discovered that such an insertion reaction may occur in the gas phase using embodiments of laser pyrolysis reactor apparatuses described herein. In some embodiments, where the organic capping agent is a gas, an embodiment of a laser pyrolysis apparatus that would result from the combination of the embodiment of laser pyrolysis apparatus 500 of FIG. 1 and laser pyrolysis reactor subassembly 600 of FIG. 3 could be used. In other embodiments, where the organic capping agent is a liquid, an embodiment of a laser pyrolysis apparatus that would result from the combination of the embodiment of laser pyrolysis apparatus 550 of FIG. 2 and laser pyrolysis reactor subassembly 600 of FIG. 3 could be used.

Some examples of organic species of interest for the organic capping of Group IV nanoparticle materials include, but are not limited by, simple alkenes and alkynes in the C2-C18 series, as well as substituted alkenes and alkynes. It is contemplated that for some embodiments of Group IV organic-capped nanoparticle materials, more polar organic moieties such as those containing heteroatoms, or amine of hydroxyl groups are indicated, while in other, aromatic groups, such as phenyl, and benzyl groups are indicated. For example, in preparing stably passivated Group IV nanoparticles with an organic capping agent using embodiments of the laser pyrolysis reactor apparatuses described in the above, a secondary precursor gas stream of short chain (C2-C9) terminal alkenes could be used at a flow rate of between about 10 sccm to about 1000 sccm of organic vapor.

Embodiments of n-type and p-type doped Group IV nanoparticle materials made be produced using embodiments of the described laser pyrolysis apparatuses. For example, an embodiment of a laser pyrolysis apparatus that could be used to produce embodiments of doped Group IV nanoparticle materials would result from the combination of the embodiment of laser pyrolysis apparatus 500 of FIG. 1, having a secondary precursor gas line 130 and laser pyrolysis reactor subassembly 600 of FIG. 3, having secondary precursor nozzles 636, 638, capable of being adjusted using secondary precursor gas nozzle height adjustment assembly 650. A variety of dopant gases are possible for use for creating doped Group IV nanoparticles. In that regard, n-type Group IV nanoparticles may be prepared using a laser pyrolysis method of preparation in the presence of well-known dopant gases such as phosphine, or arsine. Alternatively, p-type semiconductor nanoparticles may be prepared using a laser pyrolysis method of preparation in the presence of dopant gases such as boron diflouride, trimethyl borane, or diborane.

### Conditions for Producing N-Doped Nanoparticles

Using a laser pyrolysis apparatus such as depicted in FIG. 1, the conditions for producing n-doped nanoparticles are: 1) a gas flow of 60 sccm of silane gas, plus a secondary precursor gas flow of 330 sccm of phosphine in the first inner laser pyrolysis reactor inlet line, such as line 221 of FIG. 1; 2) an hydrogen sheath gas flow through second outer laser pyrolysis reactor inlet line, such as second outer laser pyrolysis reactor inlet line 223 of FIG. 1 of about 500 sccm; 3) an optical port purge, such as for optical ports 203 and 205 of FIG. 1 using a helium flow rate of 2000 sccm through a chamber purge gas line, such as chamber purge gas line 140 of FIG. 1; and 4) a laser power of between about 50 W to about 250 W, with a beam height (H₁ of FIG. 4) of about 2.0 mm.

The chamber pressure under these conditions will be between about 400 Torr to about 500 Torr. It should also be noted that the phosphine secondary precursor gas source, such as secondary precursor gas source 131 of FIG. 1, would be in the range of about 0.0018% to about 1.8% for the phosphorous dopant to be in the range of between about 5×10¹⁸ atom/cc silicon to about 5×10²¹ atom/cc silicon.

### Conditions for Producing P-Doped Nanoparticles

The conditions for producing an embodiment of p-doped nanoparticles are: 1) a gas flow of 60 sccm of silane gas, plus a secondary precursor gas flow of 330 sccm of diborane in the first inner laser pyrolysis reactor inlet line, such as line 221 of FIG. 1; 2) a hydrogen sheath gas flow through second outer laser pyrolysis reactor inlet line, such as second outer laser pyrolysis reactor inlet line 223 of FIG. 1 of about 500 sccm; 3) an optical port purge, such as for optical ports 203 and 205 of FIG. 1 using a helium flow rate of 2000 sccm through a chamber purge gas line, such as chamber purge gas line 140 of FIG. 1; and 4) a laser power of between about 50 W to about 250 W, with a beam height (H₁ of FIG. 4) of about 2.0 mm.

The chamber pressure under these conditions will be between about 400 Torr to about 500 Torr. It should also be noted that the diborane secondary precursor gas source, such as secondary precursor gas source 131 of FIG. 1, would be in the range of about 0.00091% to about 0.91% for the boron dopant to be in the range of between about 5×10¹⁸ atom/cc silicon to about 5×10²¹ atom/cc silicon.

While principles of the disclosed of Group IV nanoparticles using embodiments of laser pyrolysis reactors have been described in connection with specific embodiments, it should be understood clearly that these descriptions are made only by way of example and are not intended to limit the scope of what is disclosed. In that regard, what has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

What is claimed is:

1. An apparatus for making a set of Group IV nanoparticles, comprising:
a top plate, the top plate further including an outlet port;
a bottom plate;
a casing extending between the top plate and the bottom plate;
a particle collector assembly configured to be in fluid communication with the outlet port;
a primary precursor tubing assembly passing through the bottom plate into the casing, the primary precursor tubing assembly including a primary precursor tubing assembly nozzle;
a set of secondary precursor tubing assemblies passing through the bottom plate into the casing, wherein each secondary precursor tubing assembly of the set of secondary precursor tubing assemblies further includes a set of secondary precursor tubing assembly nozzles positioned orthogonally to the primary precursor tubing assembly nozzle, the set of secondary precursor tubing assembly nozzles further configured to be adjusted to a first height above primary precursor tubing assembly nozzle; and
a laser configured to generate a laser beam, the laser beam being substantially perpendicular to the primary precursor tubing assembly nozzle in the reaction zone, wherein the laser may be adjusted to a second height above primary precursor tubing assembly nozzle.

2. The apparatus of claim 1, wherein the primary precursor tubing assembly further includes an inner conduit and an outer conduit, wherein the inner conduit is configured to flow a primary precursor gas, and the outer conduit is configured to flow a sheath gas.

3. The apparatus of claim 2, wherein the primary precursor gas is silane.

4. The apparatus of claim 3, wherein the primary precursor gas has a primary precursor gas rate of between about 40 sccm and about 60 sccm.

5. The apparatus of claim 2, wherein the sheath gas is one of helium and hydrogen.

6. The apparatus of claim 5, wherein the sheath gas is flowed at a sheath gas flow rate of between about 500 sccm and about 1000 sccm.

7. The apparatus of claim 1, wherein the set of secondary precursor tubing assemblies is configured to flow a set of secondary precursor gases.

8. The apparatus of claim 1, wherein the set of secondary precursor gases includes at least one of a dimethyl zinc gas, a hydrogen sulfide gas, a short chain (C2-C9) terminal alkene gas, a phosphine gas, and a diborane gas.

9. The apparatus of claim 1, wherein the laser is a carbon dioxide laser.

10. The apparatus of claim 1, wherein the laser is configured to deliver between about 30 W and about 300 W.

11. The apparatus of claim 1, further including a stage mounted on a shaft connected to a handle, wherein the first height may be adjusted by adjusting the handle.

12. A method for creating an organically capped Group IV semiconductor nanoparticle, comprising:
flowing a Group IV semiconductor precursor gas into a chamber;
generating a set of Group IV semiconductor precursor radical species from the Group IV semiconductor precursor gas with a laser pyrolysis apparatus, wherein the set of the Group IV semiconductor precursor radical species nucleate to form the Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

13. The method of claim 12, wherein the Group IV semiconductor precursor gas is one of silane, disilane, germane, and digermane.

14. The method of claim 12, wherein the organic capping agent precursor gas includes at least one of an alkene, an alkyne, an amine, a phenyl, and a benzyl.

15. The method of claim 12, wherein the organically capped Group IV semiconductor nanoparticle has a diameter of between about 1 nm and about 100 nm.

16. The method of claim 12, wherein the organically capped Group IV semiconductor nanoparticle is one of a single-crystalline nanoparticle, a polycrystalline nanoparticle, and an amorphous nanoparticle.

17. A method for creating an organically capped Group IV semiconductor nanoparticle, comprising:
flowing a Group IV semiconductor precursor gas into a chamber;
flowing a dopant precursor gas into the chamber;
generating a set of Group IV semiconductor precursor radical species from the Group IV semiconductor precursor gas and the dopant precursor gas with a laser pyrolysis apparatus, wherein the set of the Group IV semiconductor precursor radical species nucleate to form a Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

18. The method of claim 17, wherein the Group IV semiconductor precursor gas is one of silane, disilane, germane, and digermane.

19. The method of claim 17, wherein the dopant precursor gas is one of boron diflouride, trimethyl borane, and diborane.

20. The method of claim 17, wherein the organic capping agent precursor gas includes at least one of an alkene, an alkyne, an amine, a phenyl, and a benzyl.

21. The method of claim 17, wherein the organically capped Group IV semiconductor nanoparticle has a diameter of between about 1 nm and about 100 nm.

22. The method of claim 17, wherein the organically capped Group IV semiconductor nanoparticle is one of a single-crystalline nanoparticle, a polycrystalline nanoparticle, and an amorphous nanoparticle.

23. An organically capped Group IV semiconductor nanoparticle, created by the method comprising:
flowing a Group IV semiconductor precursor gas into a chamber;
generating a set of Group IV semiconductor precursor radical species from the Group IV semiconductor precursor gas with a laser pyrolysis apparatus, wherein the set of the Group IV semiconductor precursor radical species nucleate to form a Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

24. The organically capped Group IV semiconductor nanoparticle of claim 23, wherein the Group IV semiconductor precursor gas is one of silane, disilane, germane, and digermane.

25. The organically capped Group IV semiconductor nanoparticle of claim 23, wherein the organic capping agent precursor gas includes at least one of an alkene, an alkyne, an amine, a phenyl, and a benzyl.

26. The organically capped Group IV semiconductor nanoparticle of claim 23, wherein the organically capped Group IV semiconductor nanoparticle has a diameter of between about 1 nm and about 100 nm.

27. The organically capped Group IV semiconductor nanoparticle of claim 23, wherein the organically capped Group IV semiconductor nanoparticle is one of a single-crystalline nanoparticle, a polycrystalline nanoparticle, and an amorphous nanoparticle.

28. An organically capped Group IV semiconductor nanoparticle, created by the method comprising:
flowing a Group IV semiconductor precursor gas into a chamber;
flowing a dopant precursor gas into the chamber;
generating a set of Group IV semiconductor precursor radical species from the Group IV semiconductor precursor gas and the dopant precursor gas with a laser pyrolysis apparatus, wherein the set of the Group IV semiconductor precursor radical species nucleate to form a Group IV semiconductor nanoparticle;
flowing an organic capping agent precursor gas into the chamber;
generating a set of organic capping agent radical species from the organic capping agent precursor gas, wherein the set of organic capping agent radical species reacts with a surface of the Group IV semiconductor nanoparticle and forms the organically capped Group IV semiconductor nanoparticle.

29. The organically capped Group IV semiconductor nanoparticle of claim 28, wherein the Group IV semiconductor precursor gas is one of silane, disilane, germane, and digermane.

30. The organically capped Group IV semiconductor nanoparticle of claim 28, wherein the dopant precursor gas is one of boron diflouride, trimethyl borane, and diborane.

31. The organically capped Group IV semiconductor nanoparticle of claim 28, wherein the organic capping agent precursor gas includes at least one of an alkene, an alkyne, an amine, a phenyl, and a benzyl.

32. The organically capped Group IV semiconductor nanoparticle of claim 28, wherein the organically capped Group IV semiconductor nanoparticle has a diameter of between about 1 nm and about 100 nm.

33. The organically capped Group IV semiconductor nanoparticle of claim 28, wherein the organically capped Group IV semiconductor nanoparticle is one of a single-crystalline nanoparticle, a polycrystalline nanoparticle, and an amorphous nanoparticle.
